(19) United States
(12) Patent Application Publication
(10) Pub. No.: US 2008/0203530 A1
(43) Pub. Date: Aug. 28, 2008

(54) SEMICONDUCTOR DEVICE AND METHOD OF PRODUCING THE SAME

(75) Inventor: Mitsushi FUJIKI, Kawasaki-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/036,844

(22) Filed: Feb. 25, 2008

(30) Foreign Application Priority Data
Feb. 23, 2007 (JP) 2007-043167

(51) Int. Cl. H01L 29/92; H01L 21/02

(52) U.S. Cl. 257/532; 438/3; 257/E29.343; 257/E21.009

(57) ABSTRACT

A semiconductor device includes a silicon substrate; a first interlayer insulating film provided on the silicon substrate; and a capacitor that is provided on the first interlayer insulating film and that includes a lower electrode, a capacitor dielectric film made of a ferroelectric substance, and an upper electrode, wherein the capacitor dielectric film does not contain a non-oriented component under the upper electrode.

### TECHNICAL FILED

This application relates to a semiconductor device and a method of producing the same.

### BACKGROUND

Recently, with the advance of digital technology, nonvolatile memories that can store and delete a large amount of data at a high speed have been developed.

The nonvolatile memories include flash memories and ferroelectric memories.

Among these, a flash memory includes a floating gate embedded in a gate insulating film of an insulated gate field-effect transistor (IGFET) and stores information by accumulating electric charges representing memory information in this floating gate. However, such a flash memory is disadvantageous in that a tunnel current must be supplied to the gate insulating film during writing or deleting of information, and a relatively high voltage is required.

On the other hand, a ferroelectric memory, which is also referred to as ferroelectric random access memory (FeRAM), stores information by utilizing a hysteresis characteristic of a ferroelectric film included in a ferroelectric capacitor. The ferroelectric film is polarized in accordance with the voltage applied between an upper electrode and a lower electrode of the capacitor, and spontaneous polarization remains even after the voltage is removed. When the polarity of the voltage applied is reversed, this spontaneous polarization is also reversed. Information can be written in the ferroelectric film by allowing the directions of the spontaneous polarization to correspond to “1” and “0”. The FeRAM is advantageous in that the voltage required for this writing is lower than that in the flash memory, and that writing can be performed at a high speed as compared with the flash memory. A system on chip (SOC) in which an FeRAM and a logic circuit are mounted in combination has been studied as an application to an IC card or the like utilizing the above advantage.

The capacitor dielectric film included in the ferroelectric capacitor is composed of, for example, a lead zirconate titanate (PZT: PbZrTiO₃) film, and various methods of forming the film are known. In particular, a PZT film can be formed by a sputtering method at low cost, and this method is advantageous in that the cost of an FeRAM can be reduced.

However, since the PZT film formed by the sputtering method is not crystallized immediately after the deposition, annealing for crystallizing PZT is necessary. This annealing is also referred to as “crystallization annealing”. As disclosed in Japanese Laid-open Patent Application Publication Nos. 2002-43310 (see paragraph 0026) and 2001-28426 (see paragraph 0052), the crystallization annealing is generally performed in an oxygen-containing atmosphere.

Since PZT has a tetragonal perovskite structure, the polarization of PZT becomes the maximum in the orientation of a <001> direction. Accordingly, ideally, it is preferable that a ferroelectric characteristic, such as the amount of switching charge, of the ferroelectric capacitor is maximized by controlling the orientation of PZT to the <001> direction by the crystallization annealing.

However, in reality, the orientation of a PZT film significantly depends on a layer provided thereunder, and thus it is difficult to control the orientation to the <001> direction.

In a semiconductor device such as an FeRAM including a ferroelectric capacitor, not only an improvement in ferroelectric characteristics but also an increase in the yield has been desired. Therefore, it is necessary to appropriately balance these two requirements.

Japanese Laid-open Patent Application Publication No. 11-220106 and PCT Publication No. 2003/023858 pamphlet also disclose techniques related to the present invention.

### SUMMARY

According to an aspect of an embodiment, a semiconductor device includes a semiconductor substrate; an insulating film provided on the semiconductor substrate; and a capacitor that is provided on the insulating film and that includes a lower electrode, a capacitor dielectric film made of a ferroelectric substance, and an upper electrode, wherein the capacitor dielectric film does not contain a non-oriented component under the upper electrode.

### BRIEF DESCRIPTION OF THE DRAWINGS

FIGS. 1A to 1C are cross-sectional views (part 1) showing steps of a method of producing a semiconductor device according to an embodiment;

FIGS. 2A and 2B are cross-sectional views (part 2) showing steps of the method of producing a semiconductor device according to the embodiment;

FIGS. 3A and 3B are cross-sectional views (part 3) showing steps of the method of producing a semiconductor device according to the embodiment;

FIGS. 4A and 4B are cross-sectional views (part 4) showing steps of the method of producing a semiconductor device according to the embodiment;

FIGS. 5A and 5B are cross-sectional views (part 5) showing steps of the method of producing a semiconductor device according to the embodiment;

FIGS. 6A and 6B are cross-sectional views (part 6) showing steps of the method of producing a semiconductor device according to the embodiment;

FIGS. 7A and 7B are cross-sectional views (part 7) showing steps of the method of producing a semiconductor device according to the embodiment;

FIGS. 8A and 8B are cross-sectional views (part 8) showing steps of the method of producing a semiconductor device according to the embodiment;

FIG. 9 is a graph obtained by analyzing the plane direction of crystallized PZT by XRD;

FIG. 10 is a graph obtained by examining the relationship between the total amount of electric power applied to a PZT target and the yield of a semiconductor device according to the embodiment;

FIG. 11 is a graph obtained by analyzing integrated intensities of the (101) plane of PZT using XRD;

FIG. 12 is a graph obtained by analyzing integrated intensities of the (100) plane of PZT using XRD;

FIG. 13 is a graph obtained by analyzing integrated intensities of the (222) plane of PZT using XRD;

FIG. 14 is a graph showing the orientation ratio of the (222) plane of PZT obtained from the results shown in FIGS. 11 to 13;

FIG. 15 is a graph showing the relationship between the orientation ratio of the (222) plane of PZT and the oxygen flow rate during crystallization annealing when a PZT target in an initial stage of use was used;

FIG. 16 is a graph showing the relationship between the oxygen flow rate during crystallization annealing and the amount Q_{SW} of switching charge of a capacitor when a PZT target in an initial stage of use was used; and

FIG. 17 is a planar transmission electron microscope (TEM) image of a capacitor Q prepared in accordance with the embodiment.

### DESCRIPTION OF THE PREFERRED EMBODIMENTS

An embodiment of the present invention will now be described in detail with reference to the attached drawings.

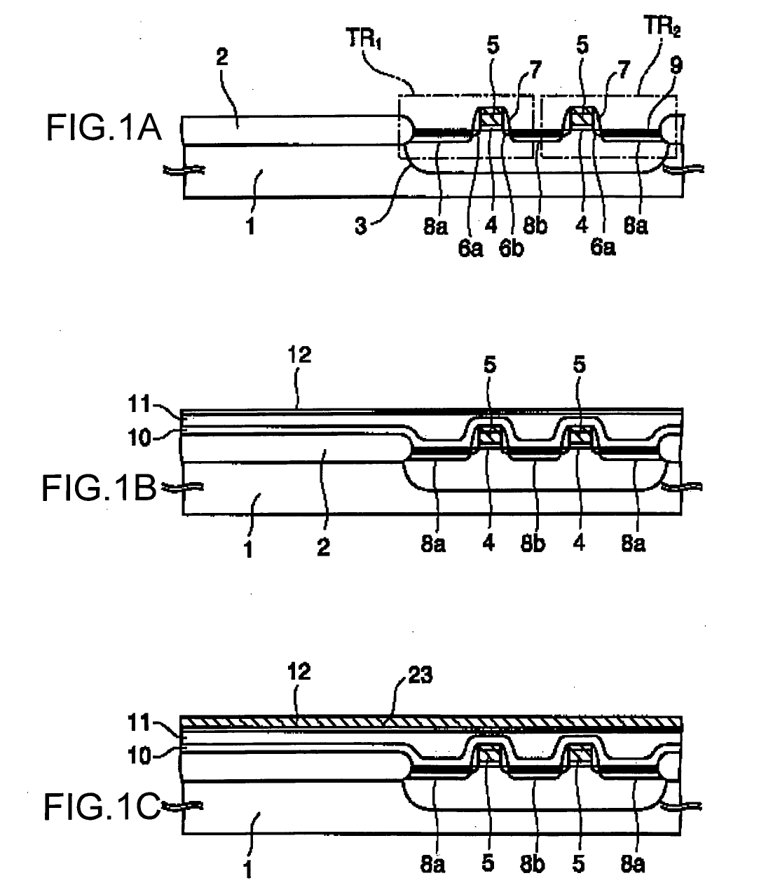

FIGS. 1A to 8B are cross-sectional views showing steps of a method of producing a semiconductor device according to this embodiment.

This semiconductor device is a planar FeRAM and is produced as follows.

First, steps of producing the cross-sectional structure shown in FIG. 1A will now be described.

An n-type or p-type silicon (semiconductor) substrate 1 is thermally oxidized to form an element separation insulating film 2. This element separation insulating film 2 defines an active region of transistors. This element separation structure is referred to as local oxidation of silicon (LOCOS). Alternatively, shallow trench isolation (STI) may be used in this step.

Subsequently, a p-type impurity such as boron is introduced into the active region of the silicon substrate 1 to form a p-well 3. The surface of the active region is then thermally oxidized to form a thermally oxidized film with a thickness in the range of about 6 to 7 nm serving as a gate insulating film 4.

Subsequently, an amorphous silicon film having a thickness of about 50 nm and a tungsten silicide film having a thickness of about 150 nm are sequentially formed on the entire upper surface of the silicon substrate 1. Alternatively, a polycrystalline silicon film may be formed instead of the amorphous silicon film. These films are then patterned by photolithography to form a gate electrode 5 on the silicon substrate 1.

Two gate electrodes 5 are formed on the p-well 3 so as to be parallel with each other and each of the gate electrodes 5 forms a part of a word line.

Furthermore, phosphorus is introduced as an n-type impurity in areas of the silicon substrate 1, the areas being located at both sides of each of the gate electrodes 5, by ion implantation using the gate electrodes 5 as a mask. Thus, first source/drain extensions 6a and second source/drain extensions 6b are formed.

Subsequently, an insulating film is formed on the entire upper surface of the silicon substrate 1. The insulating film is etch-backed, and remains as insulating side walls 7 at both sides of each of the gate electrodes 5. For example, a silicon oxide film is formed as the insulating film by a chemical vapor deposition (CVD) method.

Subsequently, an n-type impurity such as arsenic is again introduced in the silicon substrate 1 by ion implantation using the insulating side walls 7 and the gate electrodes 5 as a mask. Thus, first source/drain regions 8a and a second source/drain region 8b are formed in areas of the silicon substrate 1, the areas being located at the lateral portions of the gate electrodes 5.

Furthermore, a refractory metal film such as a cobalt film is formed on the entire upper surface of the silicon substrate 1 by a sputtering method. The refractory metal film is allowed to react with silicon by heating. Accordingly, a refractory metal silicide layer 9 such as a cobalt silicide layer is formed on the first source/drain regions 8a and the second source/drain region 8b in the silicon substrate 1 to decrease the resistance of each of the source/drain regions 8a and 8b.

The unreacted refractory metal film disposed on the element separation insulating film 2 and the like is then removed by wet etching.

By performing the above-described steps, a first MOS transistor TR₁ and a second MOS transistor TR₂ each composed of the gate insulating film 4, the gate electrode 5, the first source/drain region 8a, the second source/drain region 8b, and the like are formed on the active region of the silicon substrate 1.

Next, as shown in FIG. 1B, a silicon oxynitride (SiON) film having a thickness of about 200 nm is formed on the entire upper surface of the silicon substrate 1 by a plasma CVD method. The silicon oxynitride film is used as a cover insulating film 10.

Furthermore, a silicon dioxide (SiO₂) film having a thickness of about 1,000 nm is formed as a first interlayer insulating film 11 on the cover insulating film 10 by a plasma CVD method using tetraethoxysilane (TEOS) gas. During the formation of this first interlayer insulating film 11, hydrogen degradation of the gate insulating film 4 is prevented by the presence of the cover insulating film 10.

Subsequently, about 200 nm of the first interlayer insulating film 11 is polished by a chemical mechanical polishing (CMP) method so that the upper surface of the first interlayer insulating film 11 is planarized.

Subsequently, annealing of the first interlayer insulating film 11 is performed at a substrate temperature of 650° C. for 30 minutes in a nitrogen atmosphere. Thus, degassing of the first interlayer insulating film 11 is performed.

Furthermore, an alumina (Al₂O₃) film is formed as a lower electrode adhesive film 12 on the first interlayer insulating film 11 by a sputtering method so as to have a thickness of about 20 nm.

Subsequently, as shown in FIG. 1C, a platinum film is formed as a first conductive film 23 on the lower electrode adhesive film 12 by a sputtering method so as to have a thickness of about 155 nm. Platinum constituting the first conductive film 23 has a self-orientation property, and the plane direction of the upper surface of the platinum film is strongly oriented in the (111) plane.

Instead of the platinum film, the first conductive film 23 may be composed of a single layer film selected from an iridium (Ir) film, a ruthenium (Ru) film, a ruthenium oxide (RuO₂) film, and a strontium ruthenium oxide (SrRuO₃) film or a stacked film including two or more of these films. The (111) plane appears on the upper surface of these films as in the case of the platinum film.

Furthermore, since the lower electrode adhesive film 12 is formed prior to the formation of the first conductive film 23, the adhesive force between the first conductive film 23 and the first interlayer insulating film 11 can be increased.

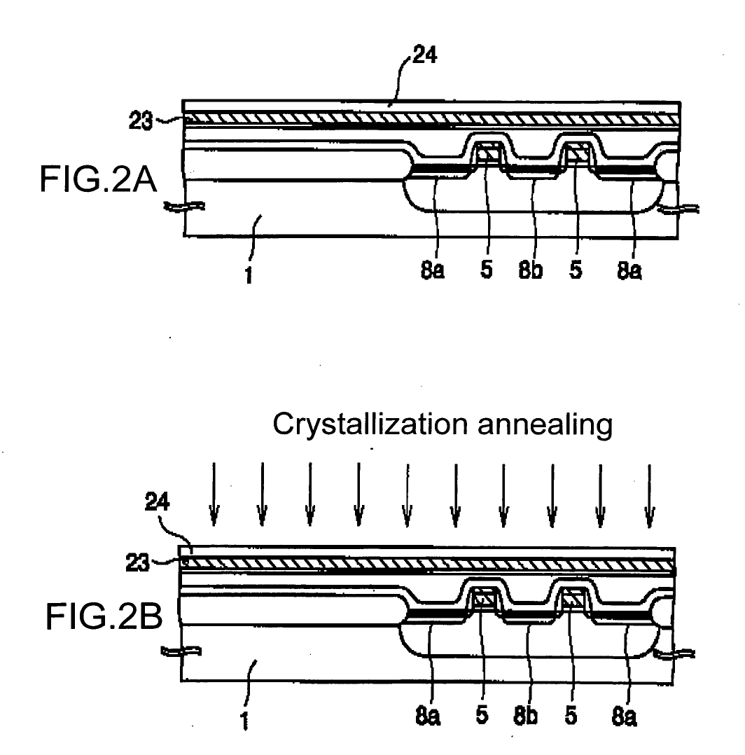

Next, as shown in FIG. 2A, a PZT film having a thickness of about 150 nm is formed as a ferroelectric film 24 on the first conductive film 23 by a radio frequency (RF) sputtering method using a PZT target.

The ferroelectric film 24 is not limited to a PZT film as long as the ferroelectric film 24 has a perovskite structure after crystallization. For example, a PLZT film prepared by doping lanthanum (La) into PZT may also be used as the ferroelectric film 24.

The ferroelectric film 24 formed by a sputtering method is not crystallized immediately after the deposition of the film but is in an amorphous state. Therefore, such a ferroelectric film 24 has poor ferroelectric characteristics.

Consequently, in order to crystallize the ferroelectric film 24, as shown in FIG. 2B, crystallization annealing of the ferroelectric film 24 is performed. The crystallization annealing is performed in an oxygen-containing atmosphere, e.g., in an atmosphere containing oxygen and argon by rapid thermal annealing (RTA). In this annealing, the substrate temperature is 563° C. and the process time is 90 seconds. Each of the flow rates of oxygen and argon will be described in detail below.

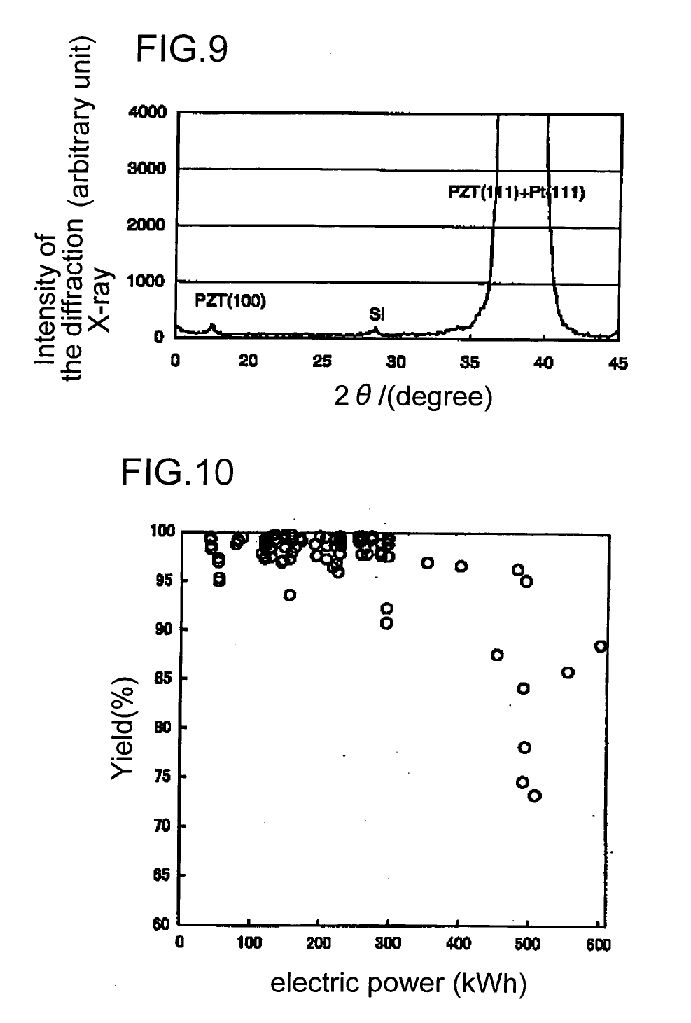

FIG. 9 is a graph obtained by analyzing the plane direction of PZT crystallized by the above crystallization annealing using an X-ray diffraction (XRD) method. The horizontal axis represents double the diffraction angle (2θ) of an X-ray. The vertical axis represents the intensity (arbitrary unit) of the diffracted X-ray.

As shown in FIG. 9, most of the PZT is preferentially oriented in the <111> direction by the action of the first conductive film 23 oriented in the <111> direction. As a result, the switching (polarization inversion) direction and the inversion electric field form an angle of 45°.

Accordingly, the ferroelectric film 24 has a polarization value that is sufficient to allow practical use of the ferroelectric film 24 as a ferroelectric capacitor, though the polarization value is lower than in the case where PZT is oriented in the <001> direction.

In FIG. 9, although the peak due to the (111) plane of PZT and the peak due to the (111) plane of the first conductive film 23 overlap with each other, these two peaks actually separate from each other in a further upper part of the graph.

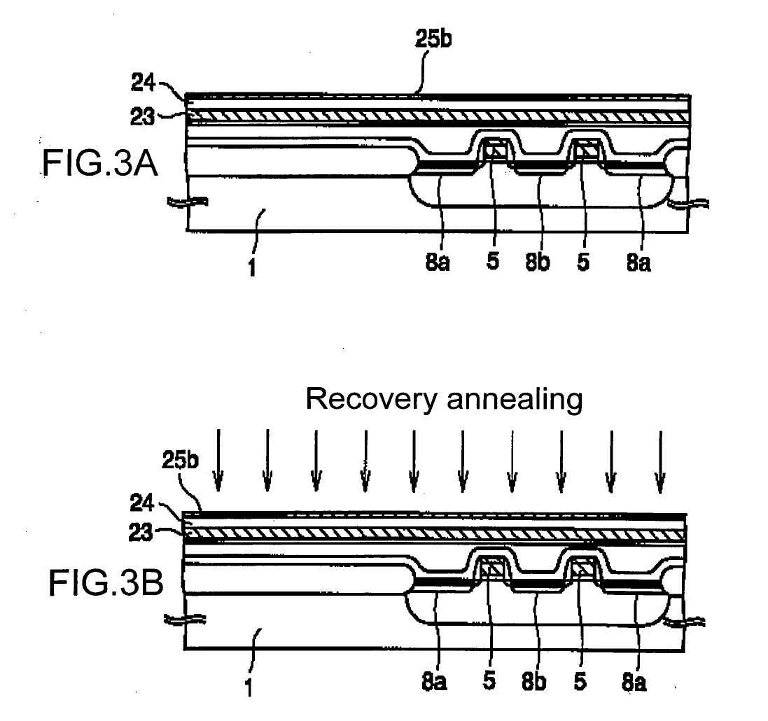

Subsequently, as shown in FIG. 3A, an iridium oxide film having a thickness of about 50 nm is formed as a first conductive noble metal oxide film 25b on the ferroelectric film 24.

This first conductive noble metal oxide film 25b forms a part of an upper electrode of a capacitor in subsequent steps. During the formation of the first conductive noble metal oxide film 25b by a sputtering method, oxygen deficiency may be generated in PZT, which forms the ferroelectric film 24. As a result, the ferroelectric characteristics of the ferroelectric film 24 may be degraded.

In order to prevent the above problem, in the subsequent step, as shown in FIG. 3B, by performing RTA in an oxygen-containing atmosphere, oxygen is supplied to the ferroelectric film 24 through the first conductive noble metal oxide film 25b to compensate for oxygen deficiency of the ferroelectric film 24 and to accelerate crystallization of the PZT in the ferroelectric film 24.

The above annealing is referred to as “recovery annealing”.

As in this embodiment, by performing the recovery annealing in a state in which the ferroelectric film 24 is covered with the first conductive noble metal oxide film 25b, lead atoms, which are essential to maintain ferroelectric characteristics of the ferroelectric film 24, are not easily diffused from the ferroelectric film 24 to the annealing atmosphere. Therefore, the effect of annealing can be increased compared with the case where the annealing is performed after the capacitor is patterned.

Furthermore, the first conductive noble metal oxide film 25b is formed so as to have a small thickness of about 50 nm. This is advantageous in that oxygen easily penetrates through the first conductive noble metal oxide film 25b, and oxygen can be easily supplied to the ferroelectric film 24.

Although conditions for the recovery annealing are not particularly limited, in this embodiment, the substrate temperature is 708° C. and the process time is 20 seconds. Furthermore, a mixed atmosphere containing oxygen gas and argon gas is used as the oxygen-containing atmosphere during annealing. The total flow rate of these gases is 2 SLM, and the oxygen flow rate is 20 sccm. According to this condition, the ratio of oxygen flow rate is 1%.

For the purpose of this description, the term “ratio of oxygen flow rate” means the percentage of the oxygen flow rate to the total flow rate of oxygen and argon.

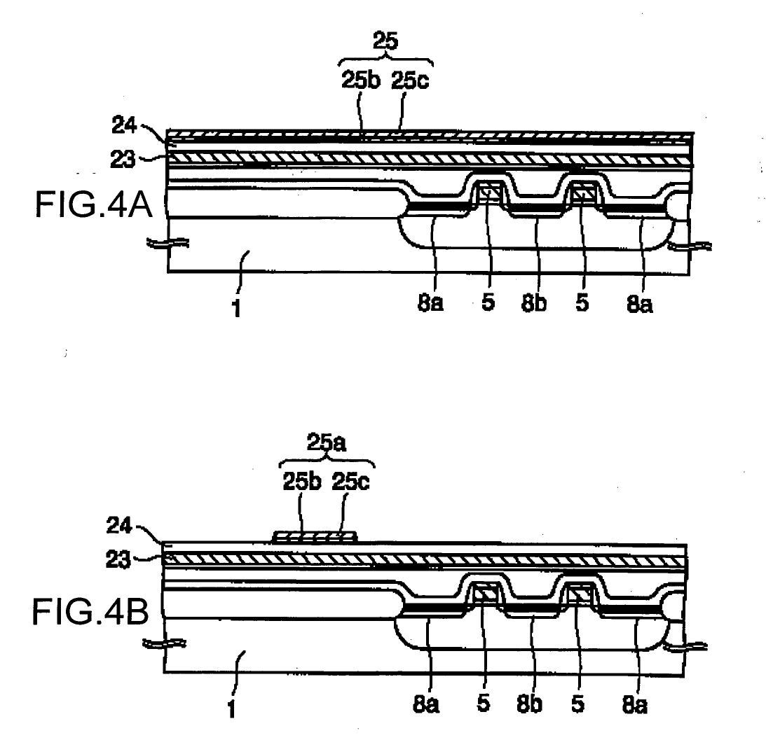

Subsequently, as shown in FIG. 4A, an iridium oxide film having a thickness of about 200 nm is formed as a second conductive noble metal oxide film 25c on the first conductive noble metal oxide film 25b by a sputtering method. The first conductive noble metal oxide film 25b and the second conductive noble metal oxide film 25c form a second conductive film 25.

As shown in FIG. 4B, the second conductive film 25 is then patterned by photolithography and dry etching to form an upper electrode 25a. Subsequently, in order that the ferroelectric film 24 recovers from damage caused by this patterning, recovery annealing of the ferroelectric film 24 is performed in a vertical furnace. This recovery annealing is performed in an oxygen-containing atmosphere. Regarding the conditions for the recovery annealing, for example, the substrate temperature is 650° C. and the process time is 60 minutes.

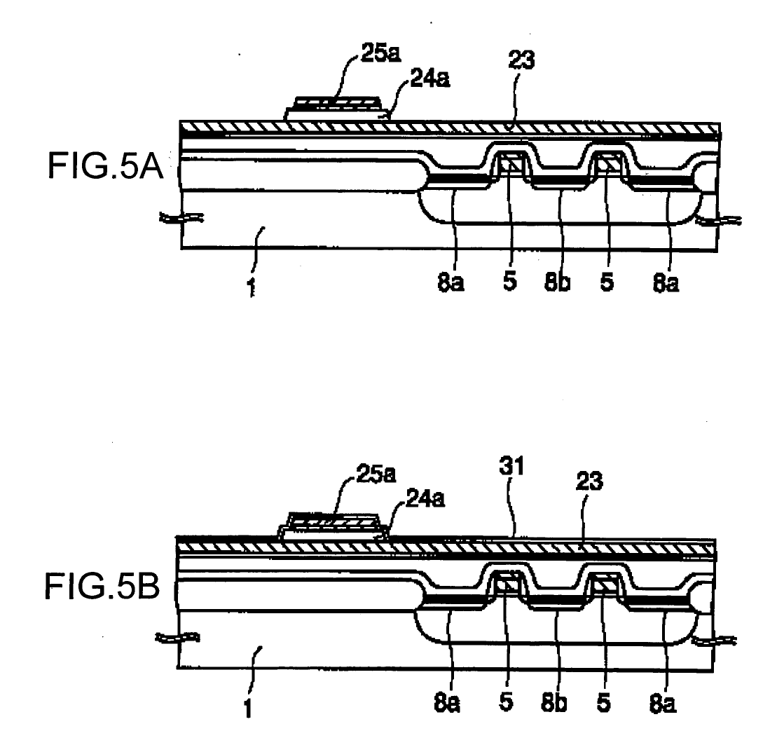

As shown in FIG. 5A, the ferroelectric film 24 is then patterned by photolithography and dry etching to form a capacitor dielectric film 24a made of PZT. Subsequently, by performing recovery annealing, the capacitor dielectric film 24a is recovered from damage caused by this patterning. This recovery annealing is performed in an oxygen-containing atmosphere using a vertical furnace as in the above-mentioned annealing. Regarding the conditions for this recovery annealing, the substrate temperature is 350° C. and the process time is 60 minutes.

Next, as shown in FIG. 5B, a first alumina film 31 having a thickness of about 50 nm is formed on the entire upper surface of the silicon substrate 1 by a sputtering method. This first alumina film 31 protects the capacitor dielectric film 24a from reducing substances such as hydrogen and moisture.

Furthermore, in order that the capacitor dielectric film 24a recovers from damage caused during the formation of the first alumina film 31, recovery annealing is performed in an oxygen-containing atmosphere at a substrate temperature of 550° C. for about 60 minutes. This recovery annealing is performed using, for example, a vertical furnace.

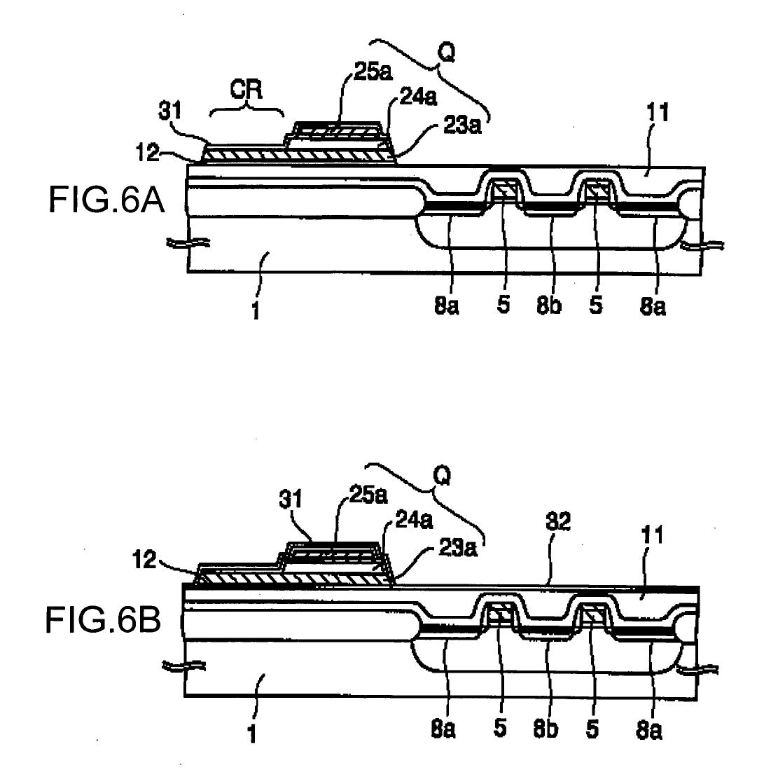

Subsequently, as shown in FIG. 6A, the first conductive film 23 and the first alumina film 31 are patterned by photolithography and dry etching. As a result, the first conductive film 23 provided under the capacitor dielectric film 24a is formed into a lower electrode 23a, and in addition, the first alumina film 31 remains so as to cover the lower electrode 23a.

In this step, a part of the lower electrode adhesive film 12 disposed in an area that is not covered with the lower electrode 23a is also removed by etching.

The lower electrode 23a includes a contact region CR that protrudes from under the capacitor dielectric film 24a. In the contact region CR, a metal wiring described below is electrically connected to the lower electrode 23a.

Subsequently, in order that the capacitor dielectric film 24a recovers from damage caused during the above process, recovery annealing of the capacitor dielectric film 24a is performed in an oxygen-containing atmosphere using a vertical furnace under the conditions of a substrate temperature of 550° C. and a process time of 60 minutes.

By performing the above steps, a capacitor Q in which the lower electrode 23a, the capacitor dielectric film 24a, and the upper electrode 25a are stacked in that order is formed in a cell region of the silicon substrate 1.

Subsequently, as shown in FIG. 6B, a second alumina film 32 for protecting the capacitor dielectric film 24a is formed on the entire upper surface of the silicon substrate 1 by a sputtering method so as to have a thickness of about 20 nm. This second alumina film 32 prevents reducing substances, such as hydrogen and moisture, from entering the capacitor dielectric film 24a together with the first alumina film 31 disposed thereunder. The second alumina film 32 and the first alumina film 31 function as films that suppress a phenomenon in which the capacitor dielectric film 24a is reduced and ferroelectric characteristics thereof are degraded.

Recovery annealing of the capacitor dielectric film 24a is then performed in an oxygen-containing atmosphere in a vertical furnace under the conditions of a substrate temperature of 550° C. and a process time of 60 minutes.

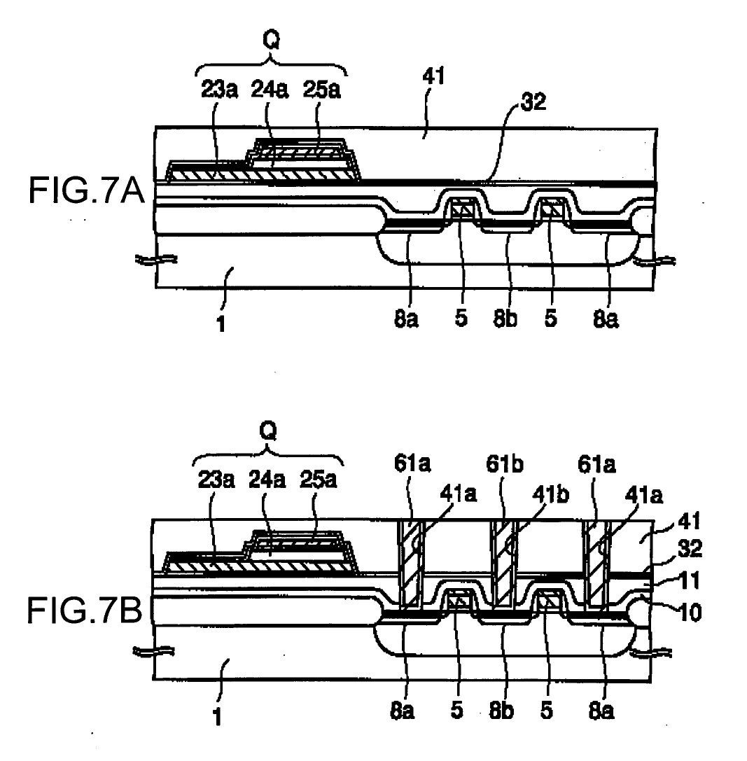

Furthermore, as shown in FIG. 7A, a silicon oxide film having a thickness of about 1,500 nm is formed on the second alumina film 32 by a high-density plasma CVD (HDPCVD) method using silane (SiH₄) gas. The resulting silicon oxide film is used as a second interlayer insulating film 41. Furthermore, the upper surface of the second interlayer insulating film 41 is planarized by polishing using a CMP method.

A N₂O plasma treatment is then performed on the second interlayer insulating film 41. Consequently, the second interlayer insulating film 41 is dehydrated, and the upper surface of the second interlayer insulating film 41 is slightly nitrided to prevent moisture from being adsorbed again.

Next, steps of producing the cross-sectional structure shown in FIG. 7B will now be described.

First, each of the cover insulating film 10, the first interlayer insulating film 11, the second alumina film 32, and the second interlayer insulating film 41 are patterned by photolithography and dry etching. Thus, first contact holes 41a and a second contact hole 41b are formed in these films disposed on the first source/drain regions 8a and the second source/drain region 8b, respectively.

A titanium film having a thickness of 20 nm and a titanium nitride film having a thickness of 50 nm are then formed by a sputtering method on the inner surfaces of the first contact holes 41a and the second contact hole 41b and on the upper surface of the second interlayer insulating film 41. These films are used as a glue film (adhesive film). Subsequently, a tungsten film is formed on the glue film by a CVD method using tungsten hexafluoride gas. The first contact holes 41a and the second contact hole 41b are completely filled with the tungsten film.

Unnecessary portions of the glue film and the tungsten film that are disposed on the second interlayer insulating film 41 are then removed by polishing using a CMP method. Accordingly, these films remain only in the first contact holes 41a and the second contact hole 41b as first conductive plugs 61a and a second conductive plug 61b, respectively. Each of the first conductive plugs 61a and the second conductive plug 61b is electrically connected to the first source/drain regions 8a and the second source/drain region 8b, respectively.

The first conductive plugs 61a and the second conductive plug 61b are mainly made of tungsten, which is very easily oxidized. Therefore, these conductive plugs are easily oxidized in an oxygen-containing atmosphere, which may result in a contact failure.

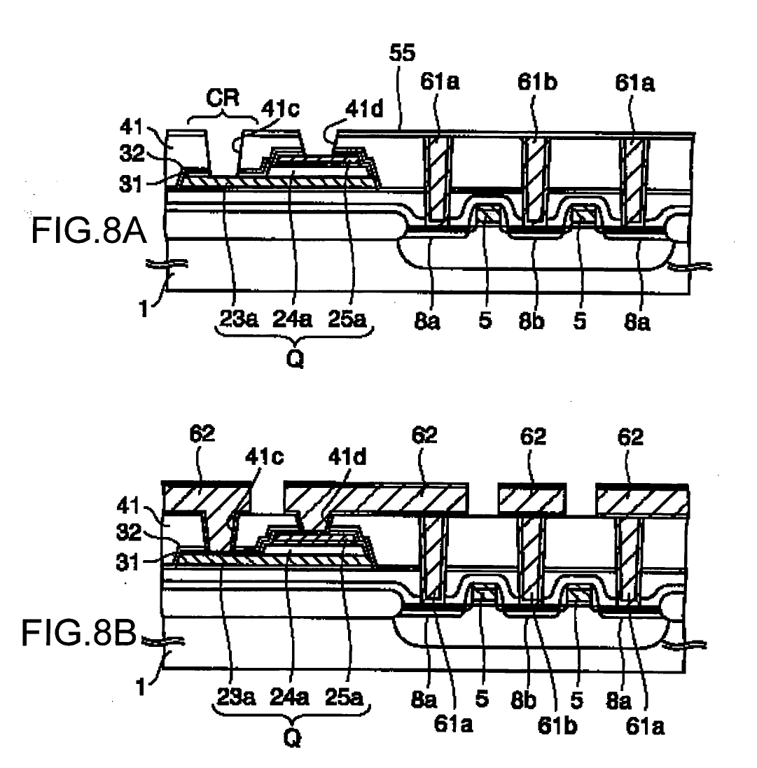

Consequently, in the subsequent step, as shown in FIG. 8A, a silicon oxynitride film having a thickness of about 100 nm is formed as an oxidation-preventing insulating film 55 on the entire upper surface of the silicon substrate 1 by a CVD method. This oxidation-preventing insulating film 55 prevents the first conductive plugs 61a and the second conductive plug 61b from being oxidized.

Subsequently, films ranging from the oxidation-preventing insulating film 55 to the first alumina film 31 are patterned by photolithography and dry etching. As a result, a third contact hole 41c is formed on the contact region CR of the lower electrode 23a, and a fourth contact hole 41d is formed on the upper electrode 25a.

Subsequently, in order that the capacitor dielectric film 24a recovers from damage caused by the previous steps, recovery annealing of the capacitor dielectric film 24a is performed. More specifically, the silicon substrate 1 is charged in an oxygen-containing atmosphere in a vertical furnace, and the recovery annealing is performed at a substrate temperature of 500° C. for 60 minutes.

Next, steps of producing the cross-sectional structure shown in FIG. 8B will now be described.

First, a metal stacked film is formed on the upper surface of the second interlayer insulating film 41, the first conductive plugs 61a, and the second conductive plug 61b by a sputtering method. In this embodiment, the metal stacked film is formed by stacking a titanium nitride film having a thickness of about 150 nm, a copper-containing aluminum film having a thickness of about 550 nm, a titanium film having a thickness of about 5 nm, and a titanium nitride film having a thickness of about 150 nm in that order. This metal stacked film is also formed in the third contact hole 41c and the fourth contact hole 41d on the capacitor Q.

The metal stacked film is then patterned by photolithography and dry etching, thus forming a metal wiring 62 that is electrically connected to the capacitor Q and the conductive plugs 61a and 61b.

The second interlayer insulating film 41 is then dehydrated by annealing in a nitrogen atmosphere of a vertical furnace under the conditions of a substrate temperature of 350° C., a nitrogen flow rate of 20 L/min, and a process time of 30 minutes.

By performing the above-described steps, the basic structure of a semiconductor device of this embodiment is produced.

Results of various examinations of this semiconductor device made by the present inventor will now be described.

As described above, in this embodiment, the ferroelectric film 24 is formed by a sputtering method using a PZT target.

FIG. 10 is a graph obtained by examining the relationship between the total amount of electric power applied to the PZT target, which is used as an indicator of the amount of PZT target used immediately before the formation of the ferroelectric film 24, and the yield of a semiconductor device prepared in accordance with the above-described embodiment.

The yield shown in FIG. 10 represents the ratio of the number of semiconductor devices that have passed predetermined reliability tests, such as a data retention property test after being left to stand at a high temperature, to the total number of semiconductor devices for which it has been confirmed that the semiconductors normally operate immediately after the production.

As shown in FIG. 10, the yield of the semiconductor device including a ferroelectric capacitor depends on the amount of PZT target used. Although the yield is high when the PZT target is in an initial stage of use, the yield tends to be decreased as the target is used.

Referring to this result, when the ferroelectric film 24 is formed by a sputtering method as in this embodiment, there is a room to optimize process conditions so as to improve the yield when a PZT target is used for a long time.

However, most defects causing a decrease in the yield shown in FIG. 10 are defects generated only in a single capacitor (i.e., defects in a single bit). Therefore, in an electrical test in which a plurality of capacitors are connected to each other and the amount of switching charges Q_{SW} is measured, it is impossible to specify which capacitors are defective. Accordingly, it is difficult to optimize the process conditions on the basis of such an electrical test.

The dependence of the above yield on the oxygen flow rate during the crystallization annealing (see FIG. 2B) was examined using a PZT target in an initial stage of use and a PZT target in a later stage of use. The results are shown in Table 1.

TABLE 1

| Flow rate of | Yield (%) | |
|---|---|---|
| O₂ gas | PZT target in initial stage of | PZT target in later stage of |
| (sccm) | use (134.0 kWh) | use (535.7 kWh) |
| 25 | 97.58 | 68.10 |
| 40 | 98.64 | 97.19 |
| 55 | 99.27 | 99.12 |
| 70 | 98.87 | 99.33 |
| 85 | 99.65 | 99.35 |
| 100 | 99.34 | 99.48 |

As shown in Table 1, in the PZT target in an initial stage of use, a relatively high yield can be achieved for any oxygen flow rate.

In contrast, in the PZT target in a later stage of use, as the oxygen flow rate increases, the yield also monotonically increases.

This result shows that, in order to eliminate the dependence of the yield on the time of the use of a target, it is effective that the oxygen flow rate during crystallization annealing is increased with an increase in the time of use of the PZT target.

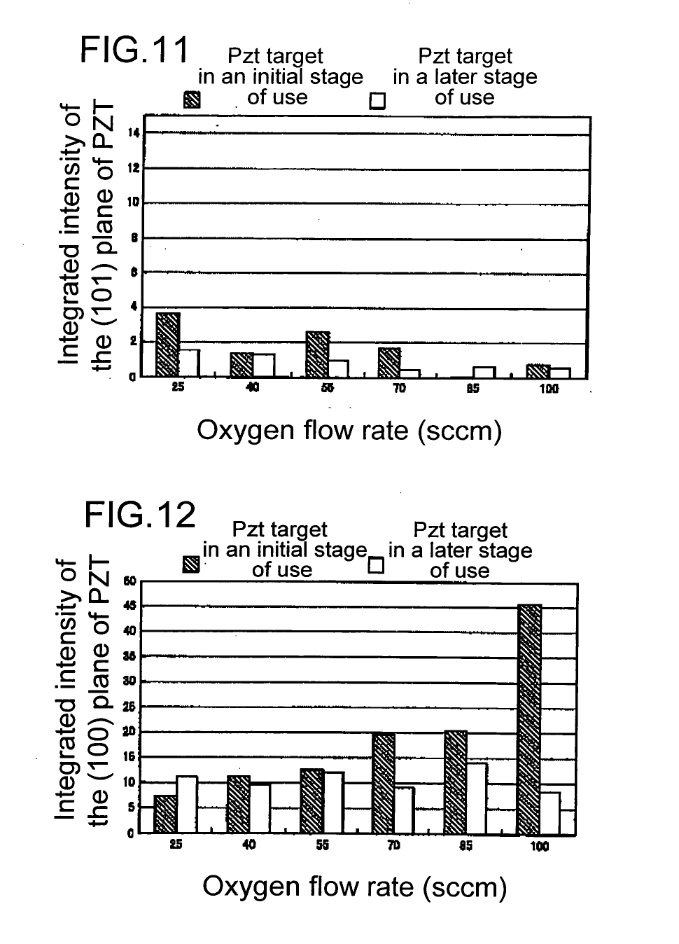

Next, the effect of the oxygen flow rate during crystallization annealing shown in FIG. 2B on the orientation of PZT constituting the capacitor dielectric film 24a will now be described with reference to FIGS. 11 to 14.

FIGS. 11 to 13 are graphs obtained by analyzing integrated intensities of the (101) plane, the (100) plane, and the (222) plane, respectively, of PZT appearing on the upper surface of a capacitor dielectric film 24a by XRD. The horizontal axis of each of the graphs represents an oxygen flow rate during crystallization annealing. These graphs show both results when a PZT target in an initial stage of use (134.0 kWh) is used and results when a PZT target in a later stage of use (535.7 kWh) is used.

As shown in FIG. 11, the integrated intensity of the (101) plane of PZT tends to be decreased by increasing the oxygen flow rate for both the PZT target in an initial stage of use and the PZT target in a later stage of use.

In contrast, as shown in FIG. 12, the integrated intensity of the (100) plane of PZT does not significantly depend on the oxygen flow rate in the PZT target in a later stage of use.

However, in the PZT target in an initial stage of use, the integrated intensity of the (100) plane tends to be increased by increasing the oxygen flow rate.

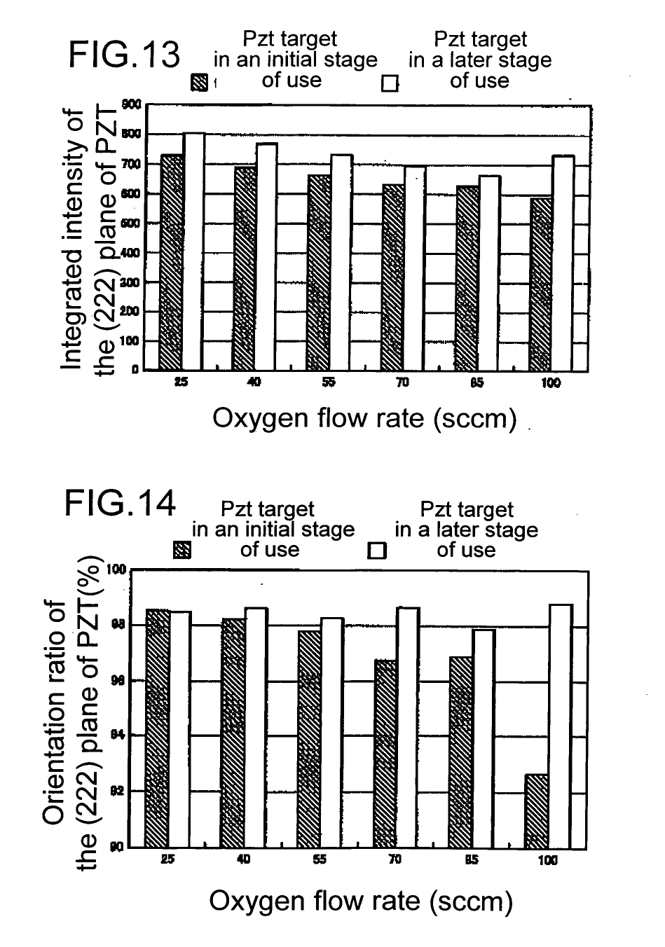

As shown in FIG. 13, regarding the (222) plane, which is equivalent to the (111) plane, in the PZT target in an initial stage of use, the integrated intensity of the (222) plane tends to decrease as the oxygen flow rate increases.

In contrast, in the PZT target in a later stage of use, the integrated intensity of the (222) plane decreases within a range from 25 to 85 sccm of the oxygen flow rate as the oxygen flow rate increases.

FIG. 14 is a graph showing the orientation ratio of the (222) plane of PZT obtained from the results shown in FIGS. 11 to 13. The orientation ratio of the (222) plane is calculated using the following formula (I):

$$Orientation ratio of PZT ( 222 ) plane = \frac{Integrated intensity of PZT ( 222 ) plane}{\begin{matrix}Integrated intensity of PZT ( 100 ) plane + \\ Integrated intensity of PZT ( 101 ) plane + \\ Integrated intensity of PZT ( 222 ) plane\end{matrix}} \qquad ( 1 )$$

As shown in FIG. 14, in the PZT target in a later stage of use, the orientation ratio of the (222) plane does not significantly depend on the oxygen flow rate during crystallization annealing.

In contrast, in the PZT target in an initial stage of use, the orientation ratio of the (222) plane tends to be decreased by increasing the oxygen flow ratio.

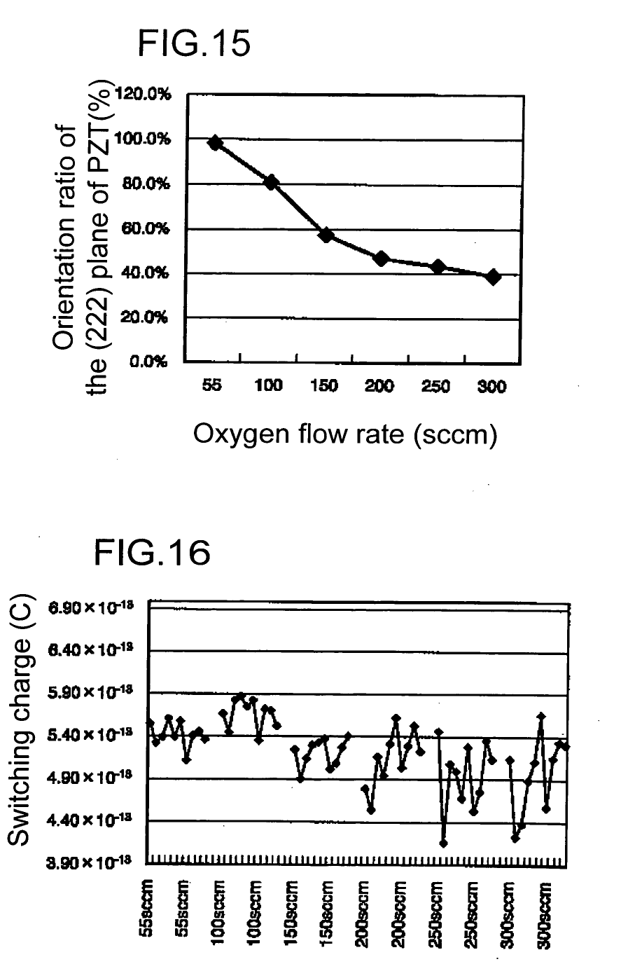

FIG. 15 is a graph showing the relationship between the orientation ratio of the (222) plane of PZT and the oxygen flow rate when the oxygen flow rate during crystallization annealing was increased to 300 sccm and a PZT target in an initial stage of use was used.

As shown in FIG. 15, as in the case described above, when the oxygen flow rate was within the range of 100 to 300 sccm, the orientation ratio of the (222) plane tended to decrease with the increase in the oxygen flow rate.

As described above, it is difficult to orient PZT in the <001> direction, in which the polarization becomes maximum. Therefore, in this embodiment, platinum that is oriented in the <111> direction is used as the lower electrode 23a so that PZT is preferentially oriented in the <111> direction. Thus, ferroelectric characteristics of the capacitor Q are improved.

Accordingly, it is believed that the lower the orientation ratio of the (222) plane, which is equivalent to the (111) plane, the lower the ferroelectric characteristics of the capacitor Q.

FIG. 16 is a graph showing the relationship between the oxygen flow rate during crystallization annealing and the amount Q_{SW} of switching charge of a capacitor Q when a PZT target in an initial stage of use (81 kWh) was used.

As is apparent from the comparison between FIG. 15 and FIG. 16, as the orientation ratio of the (222) plane of PZT decreases with an increase in the oxygen flow rate, the amount Q_{SW} of switching charge also tends to slightly decrease.

These results show that, in order to improve a ferroelectric characteristic of the capacitor Q, such as the amount Q_{SW} of switching charge, it is effective for decreasing the oxygen flow rate during crystallization annealing so as to increase the orientation ratio of the (222) plane of PZT.

However, no specific correlation between the ferroelectric characteristic of the capacitor Q and the yield was derived from the above results shown in FIGS. 11 to 16 in both the PZT target in an initial stage of use and the PZT target in a later stage of use.

For example, in the case of the PZT target in an initial stage of use, high yields are achieved regardless of the oxygen flow rate (Table 1), whereas the orientation ratio of the (222) plane is decreased when the oxygen flow rate is increased (FIG. 14). Accordingly, no specific correlation is found between the ferroelectric characteristic of the capacitor Q and the yield.

In addition, in the case of the PZT target in a later stage of use, the yield is low when the oxygen flow rate is as low as 25 sccm (Table 1), whereas a relatively high orientation ratio of the (222) plane is maintained when the oxygen flow rate is 25 sccm (FIG. 14). Accordingly, no specific correlation is found between the ferroelectric characteristic and the yield.

As described above, when a PZT target is used for a long period of time, increasing the oxygen flow rate during crystallization annealing is effective for improving the yield, as shown in Table 1. However, which orientation component of a PZT film is the factor responsible for such an improvement in the yield could not be specified from the results shown in FIGS. 11 to 15.

Consequently, It is examined that which orientation component of a PZT film was the factor responsible for an improvement in the yield.

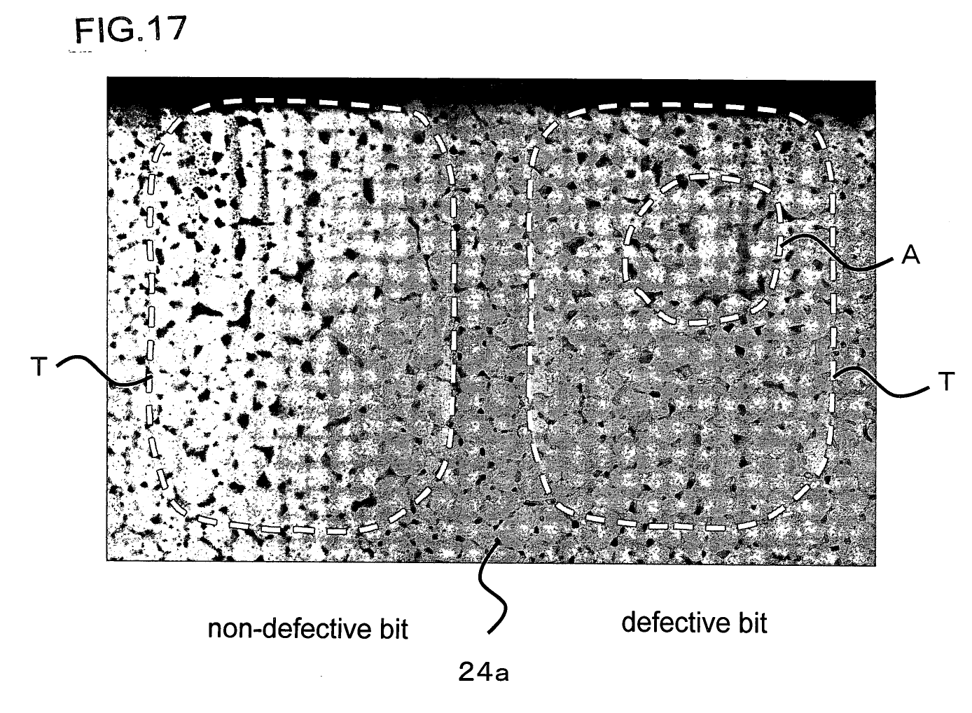

FIG. 17 is a planar transmission electron microscope (TEM) image of a capacitor Q prepared in accordance with the above-described embodiment.

In the observation with the TEM, the upper electrode 25a and the lower electrode 23a were separated from the capacitor dielectric film 24a, and an electron beam was irradiated from above the capacitor dielectric film 24a. Therefore, a trace T of the upper electrode 25a remains in FIG. 17.

A capacitor dielectric film 24a in which a non-defective bit and a defective bit were adjacent to each other was selected as a sample for the observation.

As shown in FIG. 17, in the non-defective bit, a cross-sectional image of PZT crystal grains of the capacitor dielectric film 24a appeared over the entire surface of the inside of the trace T of the upper electrode 25a with a sharp contrast.

On the other hand, in the defective bit, an area with a low brightness (abnormal contrast area) A was observed in the PZT crystal grains inside the trace T. In this example, the observation with the TEM was performed in a bright-field image, but such an abnormal contrast area A was also observed in the defective bit in a dark-field image.

Consequently, it is believed that this abnormal contrast area A was the cause of the defect and analyzed the crystal orientations of the capacitor dielectric film 24a of the non-defective bit and the defective bit by electron beam diffraction.

According to the result, in the non-defective bit, PZT of the capacitor dielectric film 24a was oriented in the <111> direction or the <100> direction over the entire surface of the inside of the trace T of the upper electrode 25a. That is, in the non-defective bit, the (111) plane or the (100) plane of PZT appeared on the upper surface of the capacitor dielectric film 24a.

On the other hand, in the defective bit, it became clear that PZT was not oriented in the above abnormal contrast area A.

According to these examination results, one of the causes of the decrease in the yield of a semiconductor device including a ferroelectric capacitor is specified as a non-oriented component of the capacitor dielectric film 24a disposed under the upper electrode 25a.

Accordingly, in order to improve the yield, the upper surface of areas of the capacitor dielectric film 24a disposed under the upper electrode 25a consists of at least one of the (111) plane (or the (222) plane, which is equivalent to the (111) plane) and the (100) plane, and the areas of the capacitor dielectric film 24a do not contain a non-oriented component.

In order that only at least one of the (111) plane and the (100) plane appears on the upper surface, it is important that the (101) plane, which is an oriented component other than the above plane, does not appear on the upper surface of the capacitor dielectric film 24a.

Referring to FIG. 11, in the case where the oxygen flow rate is 85 sccm or more, the integrated intensity of the (101) plane of PZT can be decreased to the level of a measurement error when either the PZT target in an initial stage of use or the PZT target in a later stage of use is used. Accordingly, in order to eliminate the (101) plane, it is sufficient that the oxygen flow rate during crystallization annealing is 85 sccm or more. In this embodiment, the total flow rate of oxygen and argon during crystallization annealing is 2 SLM. This is equivalent to a condition that the ratio of oxygen flow rate in the atmosphere is 4.25% or more.

However, when the (100) plane ratio is increased on the upper surface of the capacitor dielectric film 24a made of PZT, the orientation ratio of the (222) plane, which is equivalent to the (111) plane, is decreased as shown in FIG. 14. Consequently, the amount Q_{SW} of switching charge of the capacitor Q is decreased as shown in FIG. 16.

Accordingly, in order to prevent a decrease in the amount Q_{SW} of switching charge, preferably, an upper limit of the oxygen flow rate during crystallization annealing is set so that the (222) plane ratio on the upper surface of the capacitor dielectric film 24a is 80% or more. The upper limit of the oxygen flow rate is, for example, 100 sccm. In this embodiment, since the total flow rate of oxygen and argon is 2 SLM, the upper limit of the oxygen flow rate is converted to 5% in terms of the ratio of oxygen flow rate. When the oxygen flow rate is 100 sccm (ratio of oxygen flow rate: 5%) or less, as shown in FIG. 15, the (222) plane ratio on the upper surface of the capacitor dielectric film 24a can be 80% or more.

According to the results of another examination made by the present inventor, it became clear that when the ratio of oxygen flow rate was 10% or less, the (111) plane ratio on the upper surface of the capacitor dielectric film 24a is 80% or more.

Accordingly, the upper limit of the ratio of oxygen flow rate is preferably 10% or less, and more preferably 5% or less.

An embodiment of the present invention has been described in detail, but the present invention is not limited thereto.

For example, the ferroelectric film 24 was formed by a sputtering method in the above embodiment. Alternatively, the ferroelectric film 24 may be formed by a sol-gel method or a metal-organic chemical vapor deposition (MOCVD) method. In the ferroelectric film 24 formed by such an alternative deposition method, the yield of a semiconductor device including a ferroelectric capacitor can be improved by eliminating a non-oriented component as described above.

The operation of the present invention will now be described.

It has been found that a non-oriented component in the capacitor dielectric film is one of the causes of a defective capacitor. In view of this finding, in the present invention, a capacitor ferroelectric film not containing a non-oriented component is provided under the upper electrode to prevent the capacitor from becoming defective. Thus, the yield of the semiconductor device can be improved.

When the capacitor dielectric film is made of a ferroelectric substance having a perovskite structure, the upper surface of the capacitor dielectric film disposed under the upper electrode preferably consists of at least one of the (111) plane (or the (222) plane, which is equivalent to the (111) plane) and the (100) plane.

A capacitor dielectric film whose upper surface consists of at least one of the (111) plane and the (100) plane can be produced by forming an amorphous ferroelectric film by a sputtering method, and then annealing the ferroelectric film in an oxygen-containing atmosphere in which the ratio of oxygen flow rate is 2% or more, more specifically, 4.25% or more.

However, when the (100) plane ratio is increased on the upper surface of the capacitor dielectric film, the orientation ratio of the (111) plane or the (222) plane are relatively decreased, and thus the amount of switching charges of a capacitor Q is decreased. Therefore, the (111) plane ratio or the (222) plane ratio on the upper surface of the capacitor dielectric film is preferably 80% or more.

A capacitor dielectric film in which the (222) plane ratio is 80% or more can be formed by controlling the ratio of oxygen flow rate to 5% or less in the above annealing in an oxygen-containing atmosphere. A capacitor dielectric film in which the (111) plane ratio is 80% or more can be formed by controlling the ratio of oxygen flow rate to 10% or less in the annealing.

Since the capacitor ferroelectric film disposed under the upper electrode does not contain a non-oriented component, the yield of a semiconductor device including a ferroelectric capacitor can be improved.

What is claimed is:

1. A semiconductor device comprising:
a semiconductor substrate;
an insulating film provided on the semiconductor substrate; and
a capacitor that is provided on the insulating film and that includes a lower electrode, a capacitor dielectric film made of a ferroelectric substance, and an upper electrode,
wherein the capacitor dielectric film does not contain a non-oriented component under the upper electrode.

2. The semiconductor device according to claim 1, wherein the ferroelectric substance has a perovskite structure.

3. The semiconductor device according to claim 2, wherein the upper surface of the capacitor dielectric film disposed under the upper electrode consists of at least one of the (111) plane and the (100) plane.

4. The semiconductor device according to claim 3, wherein the (111) plane ratio on the upper surface of the capacitor dielectric film disposed under the upper electrode is in the range of 80% to 100%.

5. The semiconductor device according to claim 1, wherein the upper surface of the lower electrode is a (111) plane.

6. The semiconductor device according to claim 5, wherein the lower electrode comprises a single layer film selected from a platinum (Pt) film, an iridium (Ir) film, a ruthenium (Ru) film, a ruthenium oxide (RuO₂) film, and a strontium ruthenium oxide (SrRuO₃) film, or a stacked film including two or more of these films.

7. The semiconductor device according to claim 2, wherein the ferroelectric substance is PZT or PLZT.

8. The semiconductor device according to claim 1, wherein the upper electrode comprises a first conductive noble metal oxide film and a second conductive noble metal oxide film provided on the first conductive noble metal oxide film.

9. The semiconductor device according to claim 8, wherein each of the first conductive noble metal oxide film and the second conductive noble metal oxide film is an iridium oxide film.

10. A method of producing a semiconductor device comprising:
forming an insulating film on a semiconductor substrate;
forming a first conductive film on the insulating film;
forming an amorphous ferroelectric film on the first conductive film;
forming a second conductive film on the ferroelectric film;
crystallizing the ferroelectric film so as to give the ferroelectric film a perovskite structure by annealing the ferroelectric film in an oxygen-containing atmosphere; and
forming a capacitor including a lower electrode, a capacitor dielectric film, and an upper electrode by patterning the first conductive film, the ferroelectric film, and the second conductive film,
wherein, when crystallizing the ferroelectric film, the ratio of oxygen flow rate in the oxygen-containing atmosphere is 2% or more.

11. The method of producing a semiconductor device according to claim 10, wherein, the ratio of oxygen flow rate is in the range of 4.25% to 10%.

12. The method of producing a semiconductor device according to claim 10, wherein a PZT film or a PLZT film is formed as the ferroelectric film.

13. The method of producing a semiconductor device according to claim 10, wherein a conductive film whose upper surface is a (111) plane is formed as the first conductive film.

14. The method of producing a semiconductor device according to claim 10, wherein a single layer film selected from a platinum (Pt) film, an iridium (Ir) film, a ruthenium (Ru) film, a ruthenium oxide (RuO₂) film, and a strontium ruthenium oxide (SrRuO₃) film, or a stacked film including two or more of these films is formed as the first conductive film.

15. The method of producing a semiconductor device according to claim 10,
wherein the forming a second conductive film comprises:
forming a first conductive noble metal oxide film on the ferroelectric film and a step of forming a second conductive noble metal oxide film on the first conductive noble metal oxide film; and
crystallizing the ferroelectric film is performed after the step of forming a first conductive noble metal oxide film and before the step of forming a second conductive noble metal oxide film in a state in which the ferroelectric film is covered with the first conductive noble metal oxide film.

16. The method of producing a semiconductor device according to claim 15, wherein an iridium oxide film is formed as each of the first conductive noble metal oxide film and the second conductive noble metal oxide film.
